(19) United States
(12) Patent Application Publication
(10) Pub. No.: US 2026/0052798 A1
(43) Pub. Date: Feb. 19, 2026

(54) PHOTODIODE AND MANUFACTURING METHOD THEREOF

(71) Applicant: Taiwan-Asia Semiconductor Corporation, Hsinchu City (TW)

(72) Inventor: Ming-Hung Wei, Hsinchu City (TW)

(21) Appl. No.: 18/986,794

(22) Filed: Dec. 19, 2024

(30) Foreign Application Priority Data
Aug. 15, 2024 (TW) 113130738

(51) Int. Cl. H10F 77/30; H10F 30/22; H10F 71/00

(52) U.S. Cl. CPC H10F 77/306; H10F 30/22; H10F 71/134

(57) ABSTRACT

A photodiode and a manufacturing method thereof are provided. The photodiode includes a light-receiving substrate and a coating layer. The coating layer covers the light-receiving substrate and has at least one surface that is non-parallel to the upper surface of the light-receiving substrate. When an external light signal passes through the coating layer, it will be received and converted into an electrical signal by the light-receiving substrate.

### CROSS-REFERENCES TO RELATED APPLICATIONS

This application claims the benefit of priority to Taiwanese Patent Application No. 113130738 filed on Aug. 15, 2024, which is hereby incorporated by reference in its entirety.

### BACKGROUND OF THE INVENTION

### FIELD OF THE INVENTION

The present invention relates to a photodiode and a manufacturing method thereof, in particular, to a photodiode that increases the absorption of external light and improves the efficiency of the photodiode and a manufacturing method thereof.

### Descriptions of the Related Art

A photodiode is an electronic device that converts external optical signals into electrical signals. The core function of a photodiode is to absorb external light as to detect optical signals and convert them into measurable electrical current. This conversion is crucial for various applications, such as optical communication, optical measurement, and image creation.

The photodiode absorbs external light using its internal semiconductor material, such as a silicon substrate. When photons enter the photodiode and are absorbed, the energy of the photons can cause electrons in the valence band to transition to the conduction band for thereby generating electron-hole pairs. These photo-carriers are then separated under the influence of the built-in electric field within the diode and result in current.

However, conventional photodiodes exhibit poor efficiency in absorbing external light during practical applications, which adversely affects the accuracy of photoelectric conversion. To improve this issue, there is an urgent need in the industry for an innovative photodiode structure to improve the photoelectric conversion efficiency mentioned above.

### SUMMARY OF THE INVENTION

The main objective of the present invention is to provide an innovative photodiode and a manufacturing method thereof, which not only increases the area of the photodiode that absorbs external light for enhancing photosensitivity. The innovative manufacturing method can also rapidly create light-absorbing regions of various shapes for expanding the angle of receiving light.

To achieve the above objective, the present invention discloses a photodiode. The photodiode includes a light-receiving substrate and a coating layer. The coating layer covers the light-receiving substrate and has at least one surface that is non-parallel to the upper surface of the light-receiving substrate. When an external light signal passes through the coating layer, it will be received and converted into an electrical signal by the light-receiving substrate.

In one embodiment of the photodiode of the present invention, a thickness of the central area of the coating layer is smaller than a thickness of the edge area of the coating layer.

In one embodiment of the photodiode of the present invention, the at least one surface of the coating layer is a concave surface, disposed on a top surface of the coating layer.

In one embodiment of the photodiode of the present invention, the at least one surface of the coating layer is a cutting surface, disposed on an edge of the coating layer.

In one embodiment of the photodiode of the present invention, the coating layer is a composite layer, and the composite layer is made by materials selected from a group consisting of silicon dioxide (SiO₂), silicon nitride (Si₃N₄), titanium oxide (TiO₂) and a combination thereof.

In one embodiment of the photodiode of the present invention, the light-receiving substrate comprises an N-type semiconductor layer, an intrinsic layer and a P-type semiconductor layer, the intrinsic layer is sandwiched between the N-type semiconductor layer and the P-type semiconductor layer, and the coating layer is disposed on the P-type semiconductor layer.

In one embodiment of the photodiode of the present invention, the photodiode system is a flip-chip photodiode and further comprises a pair of electrodes disposed on one side of the N-type semiconductor layer.

To achieve the above objective, the present invention discloses a manufacturing method of a photodiode. The manufacturing method comprises the following steps: first, providing a coating layer, covering a light-receiving substrate thereon; second, providing a laser to cut the coating layer to form at least one surface, non-parallel to the upper surface of the light-receiving substrate, wherein after an external light signal passes through the coating layer, the external light signal will be received and converted into an electrical signal by the light-receiving substrate.

In one embodiment of the manufacturing method of the present invention, the step of providing a laser to cut the coating layer is to provide a laser to cut the coating layer to form a concave surface disposed on a top surface of the coating layer.

In one embodiment of the manufacturing method of the present invention, the step of providing a laser to cut the coating layer is to provide a laser to cut the coating layer to form a cutting surface disposed on an edge of the coating layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic cross-sectional view of the photodiode in one embodiment of the present invention;

FIG. 2 is a schematic view of the photodiode in one embodiment of the present invention;

FIG. 3 is a perspective schematic view of the photodiode in one embodiment of the present invention;

FIG. 4 is a schematic view of the manufacturing process of the photodiode of the present invention;

FIG. 5 is a schematic view of the laser stealth cutting process for the photodiode of the present invention; and

FIG. 6 is a schematic view of the process steps of manufacturing the photodiode in one embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

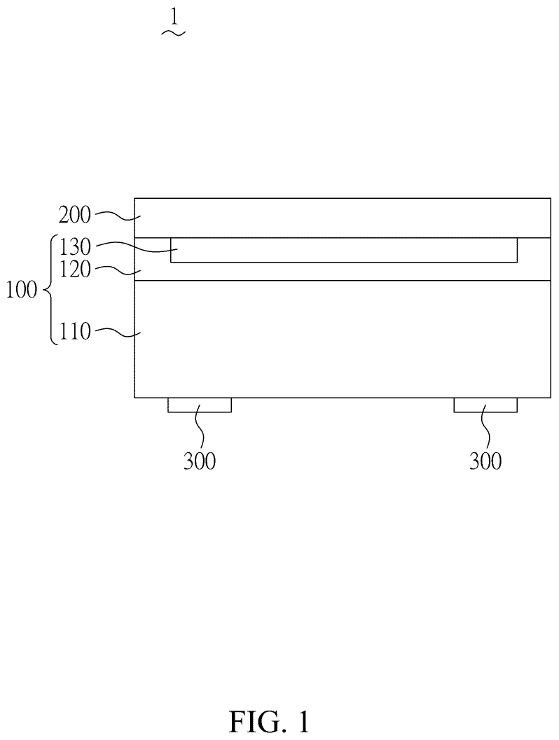

The present invention discloses a photodiode, as shown in FIG. 1. In one embodiment of the invention, the photodiode 1 is a flip-chip type photodiode, which includes a light-receiving substrate 100, a coating layer 200, and a pair of electrodes 300. The coating layer 200 covers the light-receiving substrate 100. Specifically, the light-receiving substrate 100 can be, for example, but not limited to, materials such as silicon (Si), germanium (Ge), and gallium arsenide (GaAs). Taking silicon as an example, the light-receiving substrate 100 includes an N-type semiconductor layer 110, an intrinsic layer 120, and a P-type semiconductor layer 130. The intrinsic layer 120 is sandwiched between the N-type semiconductor layer 110 and the P-type semiconductor layer 130. Specifically, the N-type semiconductor layer 110 is typically doped with phosphorus (P) or arsenic (As) in the silicon substrate to provide majority carriers for forming part of the photodiode PN junction. The intrinsic layer 120 is made by high-purity undoped intrinsic silicon for serving as the main light absorption region and allowing photons to generate electron-hole pairs. The thickness of this layer directly affects the photoelectric conversion efficiency and response speed. Additionally, the P-type semiconductor layer 130 is typically doped with boron (B) or aluminum (Al) in the silicon substrate for forming the other part of the photodiode PN junction to provide holes.

The coating layer 200 is primarily disposed on top of the P-type semiconductor layer 130. In specific embodiments, the coating layer 200 can be a composite layer structure, including anti-reflective layers, protective layers, and several other structural layers which is formed by materials selected from a group consisting of silicon dioxide (SiO₂), silicon nitride (Si₃N₄), and titanium oxide (TiO₂) and a combination thereof to achieve functions like anti-reflection, protection, and enhanced photosensitivity. Furthermore, the photodiode shown in the invention is in a flip-chip packaging format. Accordingly, the photodiode 1 also includes a pair of electrodes 300 disposed on one side of the N-type semiconductor layer 110.

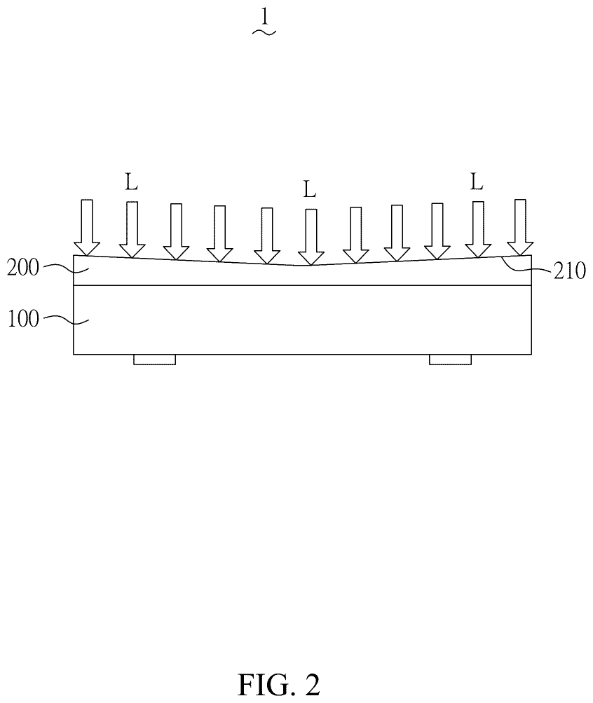

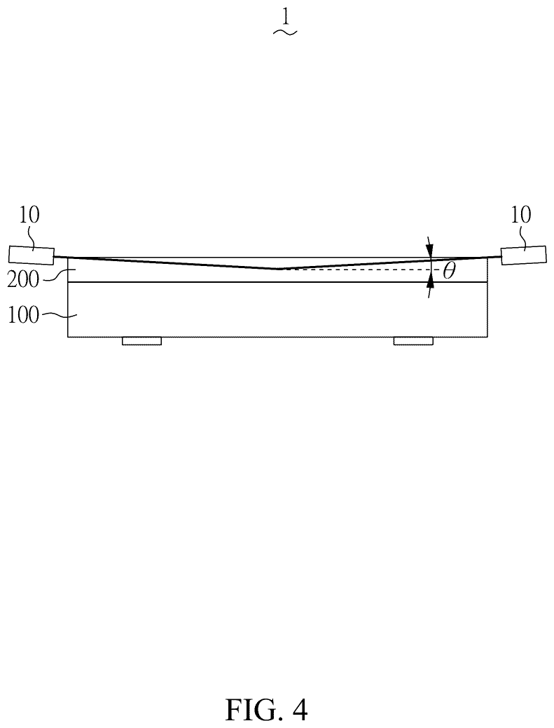

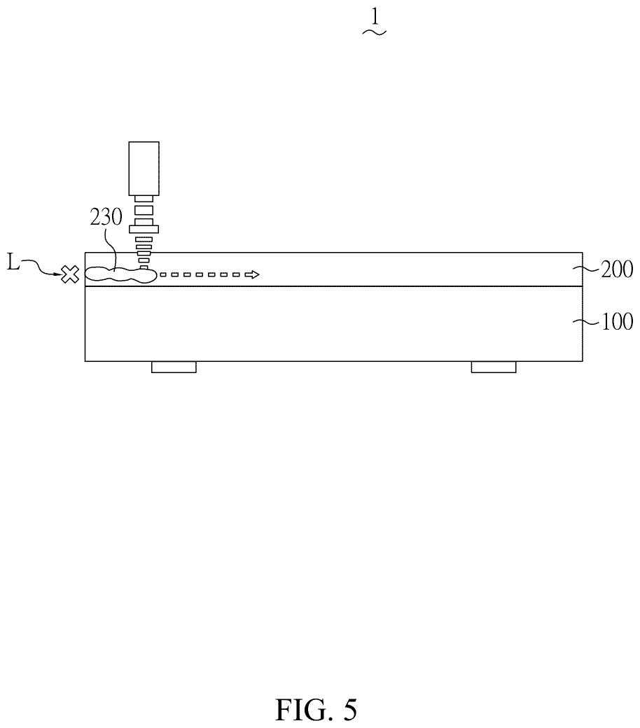

It should be noted that to increase the light absorption area of the photodiode 1, the invention utilizes laser for cutting the coating layer 200 to change the light-receiving angle thereof to create at least one surface of the coating layer that is non-parallel to the upper surface of the light-receiving substrate 100. This configuration allows the coating layer to more easily receive external light signals, which are then absorbed and converted into electrical signals by the light-receiving substrate. Specifically, referring to FIG. 2 to FIG. 4, two laser light sources 10 are arranged on both sides of the photodiode 1, such that the laser beams produced by the two laser light sources 10 converge on the surface of the coating layer 200. By concentrating the laser energy on a small area of the coating layer surface in a very short period, local heating occurs for causing the material of the surface of the coating layer to absorb the laser energy and be evaporated thermally till the desired pattern is achieved. As shown in FIG. 5, the laser beam is directed at an angle θ (the angle between the laser beam and the upper surface of the light-receiving substrate), where 0°<θ<180°, to perform a process of pattern cutting on the coating layer 200 and to form one or more surfaces on the coating layer 200 that are non-parallel to the upper surface of the light-receiving substrate 100.

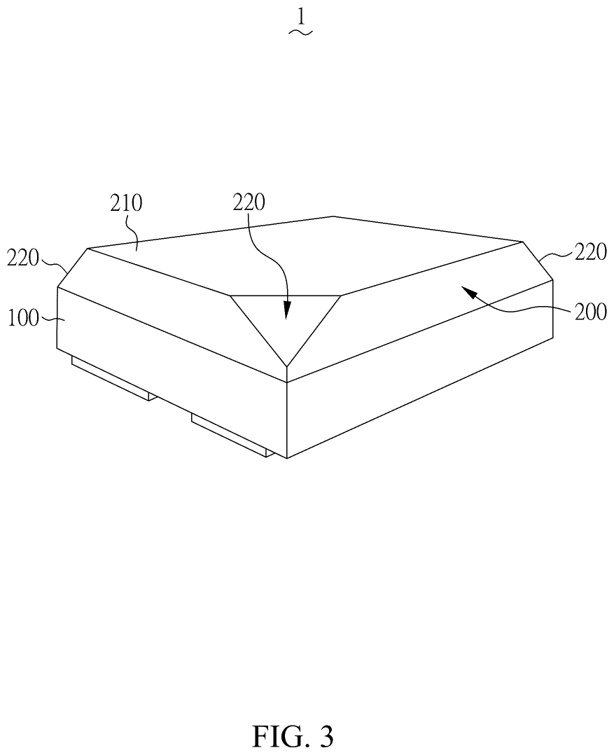

For example, as shown in FIG. 2, when the laser beam converges on the top surface of the coating layer 200 at a smaller incident angle θ, a concave surface 210 is formed on the top surface of the coating layer 200 after brief heating for resulting in the thickness of the central area of the coating layer 200 less than that of the edge area of the coating layer 200. For external light L, this concave surface 210 increases the light-receiving area and thus the photosensitivity of the photodiode is enhanced. Moreover, the concave surface 210 acts like a concave lens for providing a substantial focusing effect and allowing external light L to be focused more easily without scattering outward. On the other hand, as shown in FIG. 3, the laser beam is used to cut along the edges of the coating layer 200 to form cutting surfaces 220 of different shapes, which further increases the light-receiving area of the coating layer surface and expands the range of angles for light collection from the side. It should be noted that the cutting surfaces 220 can be formed at various corners or along all edges of the top surface of the coating layer 200 through complete or partial cutting. Additionally, based on actual needs, both the concave surface 210 and the cutting surface 220 can be formed on the surface of the coating layer 200, or either can be formed individually, both of which are specific implementable aspects of the present invention, and will not be further elaborated here.

Referring to FIG. 5, it shows that in one embodiment, the invention employs invisible laser cutting to process the photodiode. Specifically, in a particular embodiment, the coating layer 200 can be patterned according to the design requirements of different devices. As illustrated, adjustments can be made to the focal length and power of the laser light source for allowing the laser beam to converge on the internal region of the coating layer 200. It results in the formation of a locally altered structure 230 in the vicinity of where the laser beam is focused. Subsequently, using a sticky expandable film to adhere to the surface of the coating layer 200, the surface portion of the coating layer 200 can be separated and removed for leaving behind the desired patterned coating layer. Furthermore, the altered structure 230 resulting from the laser irradiation can serve as a means to effectively block external light L from entering the light-receiving substrate 100 for achieving the intended design effect of the device.

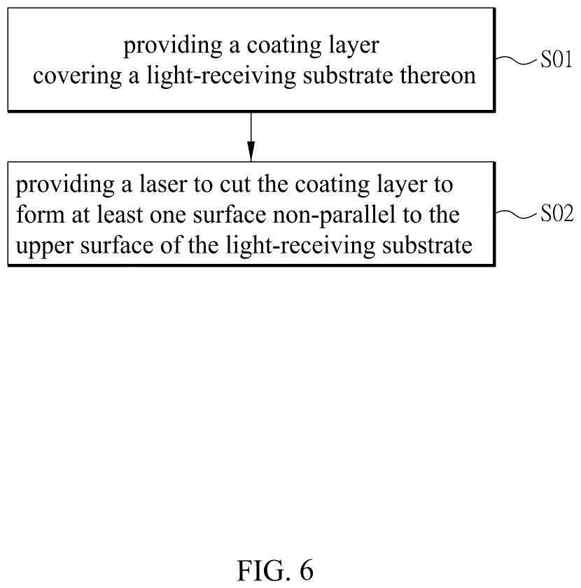

Referring to FIG. 6, it shows that the manufacturing method of the photodiode of the present invention. The method includes the following steps: first, in step S01, providing a coating layer that covers a light-receiving substrate. Second, in step S02, a laser is provided to cut the coating layer for forming at least one surface that is non-parallel to the upper surface of the light-receiving substrate. Thereby, the non-parallel surface allows external light signals to smoothly pass through the coating layer and to be absorbed and converted into electrical signals by the light-receiving substrate. Additionally, the step of providing a laser to cut the coating layer includes forming a concave surface on the top surface of the coating layer, or alternatively, forming a cutting surface along the edge of the coating layer.

In summary, the invention employs a laser cutting method to create an innovative structure of a photodiode. This structure differs from conventional photodiode structures in that it has a larger light-receiving area and a wider light-collecting angle for enhancing the photosensitivity of the photodiode and indirectly improving the photoelectric conversion efficiency. Moreover, it is particularly noteworthy that the invention utilizes the flexible processing advantages of laser cutting, which not only minimizes thermal loads on the surface of the device during processing but also results in a smoother surface compared to traditional rotary blade cutting methods. The laser cutting can significantly reduce structural debris generated during the cutting process. Moreover, the laser cutting angles are more manageable and cutting losses are minimized for fine and complex processing on the surface of the coating layer while also reducing processing time.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A photodiode, comprising:
a light-receiving substrate; and
a coating layer, covering the light-receiving substrate thereon and having at least one surface, non-parallel to the upper surface of the light-receiving substrate,
wherein after an external light signal passes through the coating layer, the external light signal is received and converted into an electrical signal by the light-receiving substrate.

2. The photodiode of claim 1, wherein a thickness of the central area of the coating layer is smaller than a thickness of the edge area of the coating layer.

3. The photodiode of claim 2, wherein the at least one surface of the coating layer is a concave surface, disposed on a top surface of the coating layer.

4. The photodiode of claim 1, wherein the at least one surface of the coating layer is a cutting surface, disposed on an edge of the coating layer.

5. The photodiode of claim 1, wherein the coating layer is a composite layer, and the composite layer is made by materials selected from a group consisting of silicon dioxide (SiO₂), silicon nitride (Si₃N₄), titanium oxide (TiO₂) and a combination thereof.

6. The photodiode of claim 1, wherein the light-receiving substrate comprises an N-type semiconductor layer, an intrinsic layer and a P-type semiconductor layer, the intrinsic layer is sandwiched between the N-type semiconductor layer and the P-type semiconductor layer, and the coating layer is disposed on the P-type semiconductor layer.

7. The photodiode of claim 1, wherein the photodiode system is a flip-chip photodiode and further comprises a pair of electrodes disposed on one side of the N-type semiconductor layer.

8. A manufacturing method of a photodiode, comprising:
providing a coating layer, covering a light-receiving substrate thereon; and
providing a laser to cut the coating layer to form at least one surface, non-parallel to the upper surface of the light-receiving substrate,
wherein after an external light signal passes through the coating layer, the external light signal is received and converted into an electrical signal by the light-receiving substrate.

9. The manufacturing method of claim 8, wherein the step of providing a laser to cut the coating layer is to provide a laser to cut the coating layer to form a concave surface disposed on a top surface of the coating layer.

10. The manufacturing method of claim 8, wherein the step of providing a laser to cut the coating layer is to provide a laser to cut the coating layer to form a cutting surface disposed on an edge of the coating layer.
